(19) United States
(12) Patent Application Publication
(10) Pub. No.: US 2014/0339458 A1
(43) Pub. Date: Nov. 20, 2014

(54) PIEZOELECTRIC CERAMIC AND PIEZOELECTRIC DEVICE CONTAINING THE SAME

(71) Applicant: TDK CORPORATION, Tokyo (JP)

(72) Inventors: Masahito FURUKAWA, Tokyo (JP); Tomohisa AZUMA, Tokyo (JP); Taku MASAI, Tokyo (JP); Yasuhiro AIDA, Tokyo (JP)

(73) Assignee: TDK CORPORATION, Tokyo (JP)

(21) Appl. No.: 13/893,930

(22) Filed: May 14, 2013

(51) Int. Cl. H01L 41/187

(52) U.S. Cl. CPC H01L 41/1873
USPC 252/62.9 PZ; 252/62.9 R

(57) ABSTRACT

A piezoelectric ceramic contains a major proportion of potassium sodium niobate and has a carbon content after firing of 55 to 1,240 ppm by mass.

### BACKGROUND OF THE INVENTION

1. Field of the Invention

The present invention relates to piezoelectric ceramics containing potassium sodium niobate and piezoelectric devices containing such piezoelectric ceramics.

2. Description of the Related Art

This type of piezoelectric ceramic is applicable to a wide variety of piezoelectric devices, including ceramic resonators, ceramic filters, piezoelectric displacement devices, piezoelectric buzzers, piezoelectric transformers, and ultrasonic transducers.

One piezoelectric ceramic frequently used in the related art is lead zirconate titanate (PZT), which has superior piezoelectric properties. PZT, however, contains a large amount of lead, which is harmful for the global environment. Accordingly, various alternatives to PZT have been developed. Among known lead-free piezoelectric materials are, for example, barium titanate (BaTiO₃) and bismuth layer ferroelectrics. Such lead-free materials, however, produce no displacement comparable to that of PZT.

For example, Japanese Patent No. 4674405 proposes a three-component lead-free material containing sodium bismuth titanate, barium titanate, and sodium niobate as a low-pollution, environmentally resistant, ecologically friendly piezoelectric ceramic.

As a piezoelectric ceramic containing a major proportion of potassium sodium niobate, which produces a relatively large displacement among lead-free piezoelectric materials, Japanese Unexamined Patent Application Publication No. 2009-049355 proposes a piezoelectric thin film having a perovskite structure represented by the general formula (KₓNa₁₋ₓ)NbO₃ (where 0<x<1).

However, such lead-free piezoelectric materials and currently used piezoelectric ceramics containing a major proportion of potassium sodium niobate produce no displacement comparable to that of PZT.

### SUMMARY OF THE INVENTION

In light of the foregoing problem, the present invention improves the displacement of a piezoelectric ceramic. In addition, the present invention provides a lead-free piezoelectric ceramic and a piezoelectric device containing such a piezoelectric ceramic for environmental protection.

A piezoelectric ceramic according to an aspect of the present invention contains a major proportion of potassium sodium niobate and has a carbon content after firing of 55 to 1,240 ppm by mass.

The inventors have found that a piezoelectric ceramic containing a major proportion of potassium sodium niobate and having a certain carbon content after firing has a high elastic constant because of its softness and thus produces a large displacement.

The carbon contained in the piezoelectric ceramic after firing is derived from materials such as a carbonate or alkoxide and an organic binder used as raw materials for the piezoelectric ceramic. To achieve a carbon content within the above desired range, a material such as a carbon powder may be optionally added as an additive in an amount of 0.1% to 1.5% by mass.

The content of potassium sodium niobate in the piezoelectric ceramic is preferably 83 to 96 mole percent. The balance may be any one of lithium tantalate, barium zirconate, and strontium zirconate, which provides better piezoelectric properties.

The piezoelectric ceramic, which contains a major proportion of potassium sodium niobate, preferably has a composition represented by formula (1):

(K_{1-x-y-w-v}NaₓLi_{y}Ba_{w}Srᵥ)ₘ(Nb_{1-z-u}Ta_{z}Zrᵤ)O₃ (1)

(wherein 0.4<x≦0.7, 0.02≦y≦0.11, 0.5≦x+y<0.75, 0<z≦0.28, 0<w≦0.02, 0.02≦v≦0.1, 0.02≦u≦0.11, and 0.95≦m<1.2).

A composition within the above ranges provides better piezoelectric properties.

The piezoelectric ceramic is applicable to a wide variety of piezoelectric devices, including ceramic resonators, ceramic filters, piezoelectric displacement devices, piezoelectric buzzers, piezoelectric transformers, and ultrasonic transducers.

The piezoelectric ceramic according to the above aspect of the present invention, which contains a major proportion of potassium sodium niobate, is environmentally friendly and produces a displacement that cannot be produced by potassium sodium niobate in the related art. If the piezoelectric ceramic has a composition within the desired ranges, it exhibits better piezoelectric properties. The present invention provides a piezoelectric device containing a piezoelectric ceramic having superior piezoelectric properties.

### BRIEF DESCRIPTION OF THE DRAWINGS

FIG. 1 is a schematic view of a piezoelectric device for displacement measurement according to an embodiment of the present invention; and

FIG. 2 is a schematic view of a displacement measuring apparatus used for displacement measurement in the Examples of the present invention.

### DESCRIPTION OF THE PREFERRED EMBODIMENTS

A piezoelectric ceramic according to an embodiment of the present invention contains a major proportion of potassium sodium niobate and has a carbon content after firing of 55 to 1,240 ppm by mass. The inventors have focused on the carbon content of a piezoelectric ceramic containing a major proportion of potassium sodium niobate after firing and have found that a larger displacement can be produced by controlling the carbon content.

The carbon contained in the piezoelectric ceramic after sintering is derived from materials such as a carbonate and an organic binder used as raw materials for the piezoelectric ceramic. To achieve a carbon content after firing within the above range, a material such as a carbon powder, a polyvinyl alcohol solution, an ethylcellulose solution, or an acrylic resin solution is added in an amount of 0.1% to 1.5% by mass of the main component of the piezoelectric ceramic on a carbon content basis. If a carbon powder is added, the amount of carbon powder added may be 0.1% to 1.5% by mass of the main composition of the piezoelectric ceramic.

The piezoelectric ceramic according to this embodiment, which contains a major proportion of potassium sodium niobate, preferably has a composition represented by formula (1):

(K_{1-x-y-w-v}NaₓLi_{y}Ba_{w}Srᵥ)ₘ(Nb_{1-z-u}Ta_{z}Zrᵤ)O₃ (1)

(where 0.4<x≦0.7, 0.02≦y≦0.11, 0.5≦x+y<0.75, 0<z≦0.28, 0<w≦0.02, 0.02≦v≦0.1, 0.02≦u≦0.11, and 0.95≦m<1.2).

In the formula, x, which represents the sodium content, satisfies 0.4<x≦0.7, preferably 0.45≦x≦0.65. Optimization of x, i.e., the sodium content, provides a larger displacement.

In the formula, y, which represents the lithium content, satisfies 0.02≦y≦0.11, preferably 0.04≦y≦0.08. Optimization of y, i.e., the lithium content, provides a higher dielectric constant and a larger displacement. If y, i.e., the lithium content, exceeds the above range, the piezoelectric ceramic cannot achieve superior piezoelectric properties because the insulation resistance decreases.

In the formula, z, which represents the tantalum content, satisfies 0<z≦0.28, preferably 0.05≦z≦0.20. Optimization of z, i.e., the tantalum content, provides a higher dielectric constant and a larger displacement. If z, i.e., the tantalum content, exceeds the above range, the piezoelectric ceramic is impractical because the Curie temperature decreases considerably.

In the formula, w, which represents the barium content, satisfies 0<w≦0.02, preferably 0.05≦w≦0.01. Optimization of w, i.e., the barium content, provides a larger displacement and a higher reliability, particularly a higher moisture resistance. If w, i.e., the barium content, exceeds the above range, the displacement decreases.

In the formula, v, which represents the strontium content, satisfies 0.02≦v≦0.1, preferably 0.03≦v≦0.07. Optimization of v, i.e., the strontium content, provides a larger displacement and a higher reliability, particularly a higher heat shock resistance. If v, i.e., the strontium content, exceeds the above range, the displacement decreases.

In the formula, u, which represents the zirconium content, satisfies 0.02≦u≦0.11, preferably 0.03≦u≦0.07. Optimization of u, i.e., the zirconium content, provides a larger displacement and a higher reliability, particularly a higher heat shock resistance. If u, i.e., the zirconium content, exceeds the above range, the displacement decreases.

In the formula, m, which represents the ratio of A-site elements (potassium, sodium, lithium, barium, and strontium) to B-site elements (niobium, tantalum, and zirconium) in the perovskite structure, satisfies 0.95≦m<1.2, preferably 0.97≦m≦1.05. Optimization of m, i.e., the ratio of A-site elements to B-site elements, provides a larger displacement and allows the piezoelectric ceramic to be stably manufactured. If m, i.e., the ratio of A-site elements to B-site elements, exceeds the above range, the displacement decreases.

The piezoelectric ceramic according to this embodiment has a Curie temperature of 200° C. or higher, at which a tetragonal-to-cubic phase transition occurs. This reduces a decrease in displacement due to an orthorhombic-to-tetragonal phase transition, which occurs generally at room temperature.

A piezoelectric device according to an embodiment of the present invention can be manufactured, for example, as follows.

Starting materials are prepared first. The starting materials are oxides, or compounds that form oxides when fired, such as carbonate, hydroxide, oxalate, nitrate, or metal alkoxide powders or solutions. These starting materials are wet-mixed, for example, in a ball mill. The powders of the starting materials preferably have an average particle size of 0.5 to 5 μm.

The mixture is then calcined. The mixture is preferably calcined at 700° C. to 1,100° C. for about 1 to 5 hours. The mixture is calcined in air, in an atmosphere with a higher partial oxygen pressure than air, or in a pure oxygen atmosphere.

The calcined mixture is then wet-pulverized, for example, in a ball mill. The calcined mixture can be wet-pulverized using water or an organic solvent such as acetone, hexane, toluene, or an alcohol such as ethyl alcohol, or a mixture of water and ethyl alcohol. The calcined mixture is preferably wet-pulverized to an average particle size of about 0.2 to 2 μm.

After the wet-pulverized powder is dried, the powder is mixed with an organic binder and is press-molded. The organic binder may be a commonly used organic binder such as polyvinyl alcohol or ethylcellulose.

After the powder is mixed with an organic binder and is press-molded, the compact is debindered. The compact is preferably debindered at 300° C. to 700° C. for about 1 to 5 hours. The compact is debindered in air, in an atmosphere with a higher partial oxygen pressure than air, or in a pure oxygen atmosphere. The residual carbon content can be controlled by adjusting the debindering temperature, time, and atmosphere.

After debindering, the compact is fired, preferably at 1,000° C. to 1,250° C. for about 0.5 to 5 hours. The compact is fired in air, in an atmosphere with a higher partial oxygen pressure than air, or in a pure oxygen atmosphere. The compact, however, may be fired in an atmosphere with a lower partial oxygen pressure than air if base metal internal electrodes are fired together, or in order to achieve desired properties.

The debindering step and the firing step may be performed either continuously or separately.

The fired compact is polished, and electrodes are formed on both sides thereof. The fired compact may be polished to any thickness. If the fired compact is polished to a thickness of about 0.1 to 2 mm, it can be easily polarized later. The electrodes may be formed in any manner using any material. For example, the electrodes may be formed by sputtering, evaporation, or baking (after screen printing) using a metal such as gold, silver, copper, platinum, nickel, or aluminum.

After the electrodes are formed, the fired compact is polarized by applying a direct-current voltage of 1 to 10 kV/mm in silicone oil at room temperature to 150° C. for 5 to 40 minutes to obtain the desired piezoelectric device.

Although the illustrated method for manufacturing the piezoelectric ceramic involves a common solid-phase process, it can also be manufactured by other processes, including sputtering and the sol-gel process.

Although embodiments of the present invention have been described, the present invention is not limited to the above embodiments. It should be appreciated that the present invention can be practiced in various manners within the scope of the present invention.

### EXAMPLES

Embodiments of the present invention are further illustrated by the following non-limiting Examples.

### Examples 1 to 5

The following starting materials were prepared: a lithium carbonate (Li₂CO₃) powder, a sodium carbonate (Na₂CO₃) powder, a potassium carbonate (K₂CO₃) powder, a strontium carbonate (SrCO₃) powder, a barium carbonate (BaCO₃) powder, a niobium oxide (Nb₂O₅) powder, a tantalum oxide (Ta₂O₅) powder, and a zirconium oxide (ZrO₂) powder. These starting materials were weighed and mixed so as to have the following composition and were wet-mixed in a ball mill:

(Na_{0.49}K_{0.38}Li_{0.06}Sr_{0.06}Ba_{0.01})_{1.16}(Nb_{0.84}Ta_{0.10}Zr_{0.06})O₃ (1)

After the starting materials were sufficiently mixed, the mixture was calcined at 800° C. for 2 hours. The calcined mixture was slurried with water and was wet-pulverized in a ball mill. The calcined mixture was wet-pulverized to an average particle size of about 1.0 μm.

After the slurry was dried, 10% by mass of polyvinyl alcohol was added as a binder to the calcined powder, and at the same time, 0.1% to 1.5% by mass of carbon powder (particle size: 5 to 8 μm) was added to the calcined powder. The results are shown in Table 1. The mixture was press-molded at a pressure of 40 MPa to form a compact having a diameter of 17 mm and a thickness of 2.7 mm.

The compact was then debindered in air at 500° C. for 1 hour and was continuously fired at 1,150° C. for 2 hours to obtain a piezoelectric sample.

The density of the as-fired sample was calculated from the mass in air and the mass in water by the Archimedes Method. The carbon content was measured using a Horiba EMIA-520 carbon/sulfur analyzer. This analyzer burns a sample in an oxygen flow by high-frequency heating and measures the carbon content based on infrared absorption. The results are shown in Table 1.

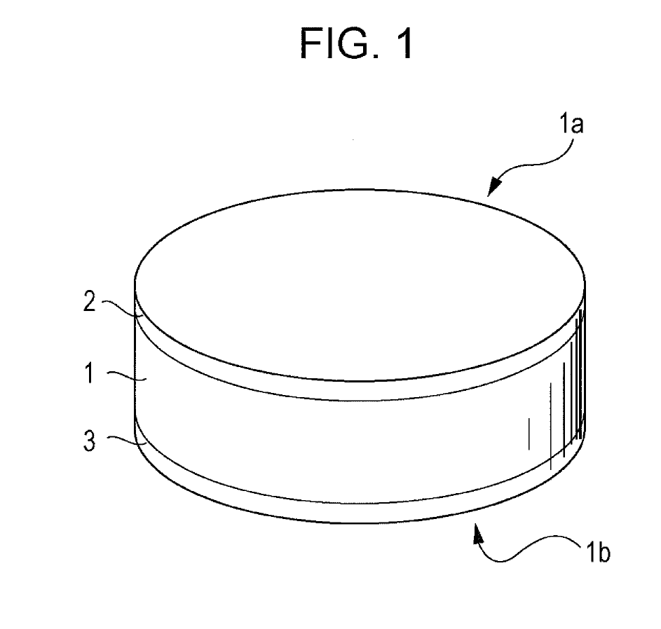

Next, the as-fired sample was polished to a thickness of 2 mm, was metallized with silver (Ag) on both main surfaces thereof, and was polarized by applying an electric field of 7.5 kV/mm in silicone oil at 150° C. for 30 minutes to obtain a displacement test sample shown in FIG. 1. The displacement test sample shown in FIG. 1 includes a piezoelectric substrate 1 and a pair of electrodes 2 and 3 and has opposing surfaces 1a and 1b.

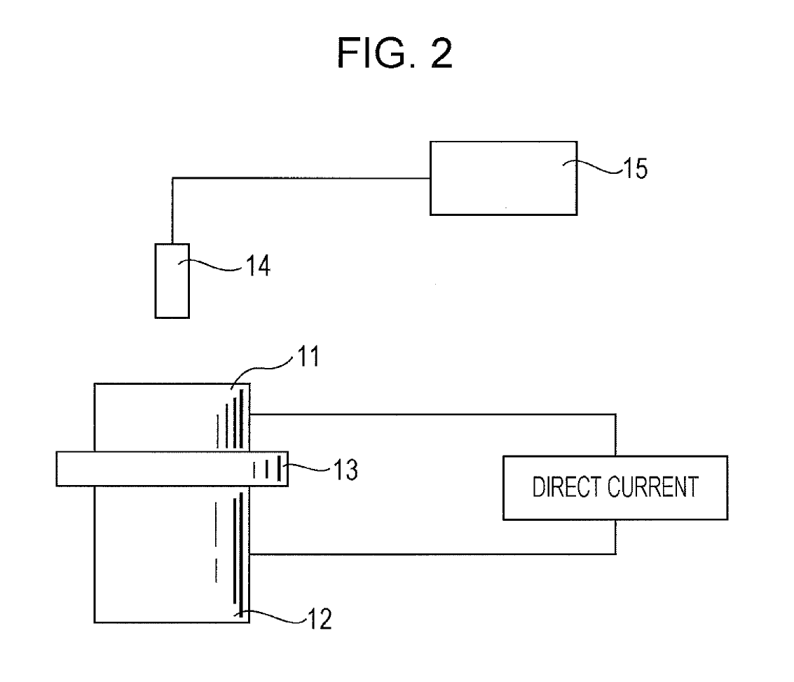

The displacement of the displacement test sample was measured using an eddy-current displacement measuring apparatus shown in FIG. 2. The displacement measuring apparatus shown in FIG. 2 holds a sample 13 between a pair of electrodes 11 and 12 and applies a direct-current voltage (2 kV/mm) across the pair of electrodes 11 and 12. The displacement of the sample 13 is sensed by a displacement sensor 14 and is determined by a displacement detector 15. The results are shown in Table 1. The displacement shown in Table 1 is the measured value divided by the thickness of the sample and multiplied by 100 (measured value/sample thickness×100).

Next, the as-fired sample was processed to form a bending strength test sample having a length of 4 mm, a width of 2 mm, and a thickness of 0.4 mm. The bending strength of the test sample was measured by a bending strength test according to JIS R1601 (Japanese Industrial Standards) using a digital load tester. The results are shown in Table 1.

### Comparative Example 1

An as-fired sample, a displacement test sample, and a bending strength test sample were fabricated under the same conditions as in Example 1 except that no carbon powder was added when the binder was added, and the density, carbon content after firing, displacement, and bending strength thereof were measured. The results are shown in Table 1.

### Comparative Example 2

An as-fired sample, a displacement test sample, and a bending strength test sample were fabricated under the same conditions as in Example 1 except that 2% by mass of carbon powder was added when the binder was added, and the density, carbon content after firing, displacement, and bending strength thereof were measured. The results are shown in Table 1.

TABLE 1

| | | Amount | | Carbon | | | |
|---|---|---|---|---|---|---|---|
| | | of carbon | Debindering | content | | Bending | |
| | | added | temperature | after firing | Displacement | strength | Density |
| | Binder | (mass %) | (° C.) | (mass ppm) | (%) | (MPa) | (g/cm³) |
| Example 1 | PVA + C | 0.1 | 500 | 55 | 0.112 | 105 | 4.53 |
| Example 2 | PVA + C | 0.2 | 500 | 231 | 0.111 | 109 | 4.54 |
| Example 3 | PVA + C | 0.5 | 500 | 472 | 0.113 | 112 | 4.56 |
| Example 4 | PVA + C | 1.0 | 500 | 967 | 0.116 | 105 | 4.53 |
| Example 5 | PVA + C | 1.5 | 500 | 1240 | 0.121 | 100 | 4.51 |
| Comparative | PVA | — | 500 | 35 | 0.085 | 120 | 4.62 |
| Example 1 | | | | | | | |
| Comparative | PVA + C | 2.0 | 500 | 1729 | — | 97 | 4.47 |
| Example 2 | | | | | | | |

These results demonstrated that if the carbon content after firing is 35 ppm by mass, as in Comparative Example 1, the piezoelectric ceramic has good bending strength, i.e., 120 MPa, although the displacement decreases.

The results also demonstrated that if the carbon content after firing is 1,729 ppm by mass, as in Comparative Example 2, the bending strength and the density decrease. In addition, the piezoelectric displacement cannot be measured because the piezoelectric ceramic cannot be polarized.

In contrast, the results demonstrated that if the carbon content after firing is 55 to 1,240 ppm by mass, as in Examples 1 to 5, the piezoelectric ceramic produces a sufficiently large displacement, i.e., 0.111% to 0.121%, and also has a high bending strength, i.e., 100 to 112 MPa.

What is claimed is:

1. A piezoelectric ceramic comprising a major proportion of potassium sodium niobate and having a carbon content after firing of 55 to 1,240 ppm by mass.

2. The piezoelectric ceramic according to claim 1, wherein the potassium sodium niobate has a composition represented by formula (1):
(K_{1-x-y-w-v}NaₓLi_{y}Ba_{w}Srᵥ)ₘ(Nb_{1-z-u}Ta_{z}Zrᵤ)O₃ (1)
(wherein 0.4<x≦0.7, 0.02≦y≦0.11, 0.5≦x+y<0.75, 0<z≦0.28, 0<w≦0.02, 0.02≦v≦0.1, 0.02≦u≦0.11, and 0.95≦m<1.2).

3. A piezoelectric device comprising the piezoelectric ceramic according to claim 1.
